(19) United States
(12) Patent Application Publication
(10) Pub. No.: US 2008/0128619 A1
(43) Pub. Date: Jun. 5, 2008

(54) Infrared Imaging Element

(76) Inventors: Shinji Yoshida, Osaka (JP); Daisuke Ueda, Osaka (JP)

Correspondence Address: MCDERMOTT WILL & EMERY LLP, 600 13TH STREET, NW, WASHINGTON, DC, 20005-3096, US

(21) Appl. No.: 10/589,619

(22) PCT Filed: Feb. 16, 2004
(86) PCT No.: PCT/JP04/01618

§ 371 Date: Aug. 16, 2006

(51) Int. Cl. G01J 1/02

(52) U.S. Cl. 250/338.1

(57) ABSTRACT

To provide an infrared imaging device having a higher temperature resolution that includes a plurality of pixel cells (1a-1d) arranged one-dimensionally or two-dimensionally, in which each pixel cell includes a thermal resistor composed of a strongly-correlated electron material.

### TECHNICAL FIELD

The present invention relates to an infrared imaging device, and specifically to an art for improving a temperature resolution thereof in a larger temperature range.

### BACKGROUND ART

In recent years, there has been a growing demand for infrared cameras such as small surveillance cameras for security and night vision cameras mounted on cars, which can recognize an object as an image in a dark field. With this demand, developments have been rapidly proceeding in infrared detectors and infrared imaging devices as principal parts of an infrared camera. There are many methods for detecting infrared lights. One representative of such methods is a bolometer method using properties of a thermal resistor whose resistance value changes in accordance with a temperature change. According to this method, a thermal resistor has a resistance value that changes in accordance with a temperature change caused by received infrared lights. An amount of received infrared light can be detected by measuring an amount of change in the resistance value.

Suitability of a material for a thermal resistor is evaluated based on TCR (Temperature Coefficient of Resistance) that shows a change ratio of an electrical resistivity that changes in accordance with a temperature change, a magnitude of electrical resistivity, noise properties in application of electric currents, and the like. TCR is particularly important for determining a temperature resolution NETD (Noise Equivalent Temperature Difference) of an infrared imaging device. Therefore, researches on material physical properties have been actively conducted in order to realize a higher TCR.

For example, Japanese Patent Application Publication No. H11-271145 discloses that vanadium oxide thin films are suitable for thermal resistors because of having a comparatively high TCR of approximately 2%/K. Furthermore, Japanese Patent Application Publication No. 2000-143243 discloses that replacement of a part of vanadium in a vanadium oxide with a different metal increases the TCR up to approximately 4%/K. As mentioned above, vanadium oxide materials and polycrystalline silicons have been conventionally used as thermal resistors of infrared imaging devices.

Also, researches have been conducted in recent years on, metal-insulator phase transitions in strongly-correlated electron materials such as transition metal oxides having a perovskite structure. Strongly-correlated electron materials are expected to be applied to an infrared detector because of having a very high TCR (approximately 10%/K) at a temperature near a metal-insulator phase transition temperature. For example, Japanese Patent Application Publication No. 2000-95522 discloses an infrared detector using La₁₋ₓSrₓMnO_{3+δ} as a thermal resistor. Moreover, Japanese Patent Application Publication No. 2003-42840 discloses an infrared detector using YBaCo₂Oₓ as a thermal resistor. Note that a method for producing A₁₋ₓBₓMnO₃ is disclosed in Japanese Patent Application Publication No. 2002-284539, for example.

Although conventional infrared imaging devices have been improved in temperature resolution by using vanadium oxide materials and the like as a thermal resistor, the arrival of an infrared imaging device having a higher temperature resolution is expected.

Also, although conventional infrared detectors have been improved in temperature resolution by using the materials mentioned in the above references, the materials have a high TCR in a very narrow temperature range. Moreover, the temperature range generally exists at a low temperature zone below room temperature. Infrared detectors need to be cooled in order to improve a temperature resolution, thereby preventing miniaturization and cost reduction in infrared detectors.

### DISCLOSURE OF THE INVENTION

The present invention firstly aims to provide an infrared imaging device having a higher temperature resolution.

The present invention secondly aims to provide an infrared detector having a higher temperature resolution in a larger temperature range.

An infrared imaging device according to the present invention includes a plurality of thermal resistors arranged one-dimensionally or two-dimensionally, wherein each of the thermal resistors is composed of a strongly-correlated electron material.

Strongly-correlated electron materials are known for undergoing a metal-insulator phase transition at a temperature, and having a very high change in an electrical resistivity in accordance with a temperature change (TCR) at a temperature near the metal-insulator phase transition temperature. Therefore, by using a strongly-correlated electron material as the thermal resistor, an infrared imaging device having a higher temperature resolution can be realized.

Also, the thermal resistor may be a metal oxide having a perovskite structure and including at least one of a rare earth metal and an alkaline earth metal.

It is particularly known, among strongly-correlated electron materials, that a metal oxide having a perovskite structure and including at least one of a rare earth metal and an alkaline earth metal has a high TCR. Therefore, by using the metal oxide as the thermal resistor, an infrared imaging device having a higher temperature resolution can be realized.

Also, the infrared imaging device may further include a detecting unit operable to detect an amount of received infrared light using the thermal resistor, and the plurality of thermal resistors and the detecting unit may be formed on a common semiconductor substrate.

With the above structure, in the infrared imaging device, the plurality of thermal resistors and the detecting unit can be manufactured as one component. This enables eliminating a wiring process of a plurality of thermal resistors and a detecting unit, and the like in an assembly process of products on which an infrared imaging device is mounted, thereby leading to cost reduction. Note that since the infrared imaging device can be manufactured based on a semiconductor process, miniaturization of each infrared detector can realize pixel increase.

An infrared camera according to the present invention includes a plurality of thermal resistors arranged one-dimensionally or two-dimensionally, and generates image data by detecting an amount of received infrared light using the thermal resistors, wherein the thermal resistor is composed of a strongly-correlated electron material.

With the above structure, the infrared camera can achieve the same effect as that in the above-described infrared imaging device.

An infrared detector according to the present invention detects an amount of received infrared light using a thermal resistor, wherein the thermal resistor is composed of Pr₁₋ₓCaₓMnO₃ having a perovskite structure in which at least one of replacement of a part of Pr with a different a rare earth metal and replacement of a part of Ca with a different alkaline earth metal is performed.

In Pr₁₋ₓCaₓMnO₃, at least one of replacement of a part of Pr with a different rare earth metal and replacement of a part of Ca with a different alkaline earth metal changes a phase transition temperature and its range width thereof. These changes differ depending on the kind of elements to replace with and an amount of replacement thereof.

Therefore, appropriate selections of a hole doping level, a kind of elements to replace with, and an amount of replacement thereof can realize an infrared detector having a higher temperature resolution in a larger temperature range. That is, an operating temperature range of the infrared detector can be extended.

An infrared detector according to the present invention detects an amount of received infrared light using a thermal resistor, wherein the thermal resistor is composed of LaTiO₃ having a perovskite structure in which a part of La is replaced with an alkaline earth metal.

In LaTiO₃, replacement of a part of a trivalent rare earth metal La with a divalent alkaline earth metal changes a temperature characteristic in an electrical resistivity thereof. The temperature characteristic in the electrical resistivity differs greatly depending on a change in a hole doping level of an alkaline earth metal.

Therefore, an appropriate selection of a hole doping level can realize an infrared detector having a higher temperature resolution in a larger temperature range. That is, an operating temperature range of the infrared detector can be extended.

An infrared detector according to the present invention detects an amount of received infrared light using a thermal resistor, wherein the thermal resistor is composed of RNiO₃ having a perovskite structure and including R in which a part of R is replaced with an alkaline earth metal, where R is an yttrium or a rare earth metal.

In RNiO₃, a change in the kind of rare earth metals R changes an insulator-metal phase transition temperature thereof.

Therefore, an appropriate selection of a kind of metals R can realize an infrared detector having an optimal specification in an operating temperature range in accordance with purposes.

Also, R in the RNiO₃ may be made by compounding two or more elements from among the yttrium and the rare earth metal.

In RNiO₃, composition of a plurality of kinds of elements of R which are either one of an yttrium and a rare earth metal changes a temperature characteristic in an electrical resistivity thereof. The temperature characteristic in the electrical resistivity greatly differs depending on a combination of elements to be compounded and a composition ratio thereof.

Therefore, appropriate selections of a combination of compounded elements and a composition ratio thereof can realize an infrared detector having a higher temperature resolution in a larger temperature range. That is, an operating temperature range of the infrared detector can be extended.

Also, the thermal resistor may be composed of RNiO₃ in which a part of R is replaced with an alkaline earth metal.

In RNiO₃, replacement of a part of a trivalent metal R with a divalent alkaline earth metal changes a temperature characteristic in an electrical resistivity thereof. The temperature characteristic in the electrical resistivity differs greatly depending on a change in a hole doping level of an alkaline earth metal.

Therefore, an appropriate selection of a hole doping level can realize an infrared detector having a higher temperature resolution in a larger temperature range. That is, an operating temperature range of the infrared detector can be extended.

An infrared detector according to the present invention includes: a thermal resistor composed of a metal oxide having a perovskite structure; a magnetic field applying unit operable to apply a magnetic field to the thermal resistor; and a detecting unit operable to, in a state where the magnetic field is being applied to the thermal resistor by the magnetic field applying unit, detect an amount of received infrared light using the thermal resistor.

With the above structure, in the infrared detector, a magnetic field can be applied to the thermal resistor. A metal-insulator phase transition temperature of the thermal resistor differs depending on an intensity of the magnetic field. This can change a temperature characteristic in an electrical resistivity of the thermal resistor. That is, an appropriate selection of an intensity of a magnetic field can realize an infrared detector having a higher temperature resolution in a larger temperature range. That is, an operating temperature range of the infrared detector can be extended.

Also, the infrared detector may further include a changing unit operable to cause the magnetic field applying unit to change an intensity of the magnetic field.

With the above structure, in the infrared detector, an intensity of a magnetic field to be applied to a thermal resistor can be changed. Therefore, by appropriately changing the intensity of the magnetic field in accordance with a change in a temperature environment of the infrared detector, the infrared detector can achieve an optimal TCR.

An infrared detector according to the present invention detects an amount of received infrared light using a thermal resistor, wherein the thermal resistor is composed of a metal oxide having a perovskite structure, and is formed on an insulator having a perovskite structure whose lattice constant differs from a lattice constant of the thermal resistor.

With the above structure, since the thermal resistor has a lattice constant different from a lattice constant of the insulator as a ground, an internal stress is generated in the thermal resistor. A metal-insulator phase transition temperature of the thermal resistor differs depending on an intensity of the internal stress. Moreover, the intensity of the internal stress differs depending on a difference in lattice constant between the thermal resistor and the insulator. A change in combination of a thermal resistor and an insulator can change a temperature characteristic in an electrical resistivity of the thermal resistor. That is, appropriate selections of a combination of a thermal resistor and an insulator can realize an infrared detector having a higher temperature resolution in a larger temperature range. And so an operating temperature range of the infrared detector can be extended.

An infrared detector according to the present invention includes: a thermal resistor composed of a metal oxide having a perovskite structure; a stress applying unit operable to apply a stress to the thermal resistor; and a detecting unit operable to, in a state where the stress is being applied to the thermal resistor by the stress applying unit, detect an amount of received infrared light using the thermal resistor.

With the above structure, in the infrared detector, a stress can be applied to the thermal resistor. A metal-insulator phase transition temperature of the thermal resistor differs depending on an intensity of the external stress. This can change a temperature characteristic in an electrical resistivity of the thermal resistor. That is, an appropriate selection of an intensity of an external stress can realize an infrared detector having a higher temperature resolution in a larger temperature range. And so an operating temperature range of the infrared detector can be extended.

Also, the infrared detector may further include a changing unit operable to cause the stress applying unit to change an intensity of the stress.

With the above structure, in the infrared detector, an intensity of a stress to be applied to the thermal resistor can be changed. Therefore, by appropriately changing the intensity of the stress in accordance with a change in a temperature environment of the infrared detector, the infrared detector can achieve an optimal TCR.

An infrared detector according to the present invention includes: a thermal resistor composed of a metal oxide having a perovskite structure; an electric field applying unit operable to apply an electric field to the thermal resistor; and a detecting unit operable to, in a state where the electric field is being applied to the thermal resistor by the electric field applying unit, detect an amount of received infrared light using the thermal resistor.

With the above structure, in the infrared detector, an electric field can be applied to the thermal resistor. A metal-insulator phase transition temperature of the thermal resistor differs depending on an intensity of the electric field. This can change a temperature characteristic in the electrical resistivity of the thermal resistor. That is, an appropriate selection of an intensity of an electric field can realize an infrared detector having a higher temperature resolution in a larger temperature range. And so an operating temperature range of the infrared detector can be extended.

Also, the infrared detector may further include a changing unit operable to cause the electric field applying unit to change an intensity of the electric field.

With the above structure, in the infrared detector, an intensity of an electric field to be applied to the thermal resistor can be changed. Therefore, by appropriately changing the intensity of the electric field in accordance with a change in a temperature environment of the infrared detector, the infrared detector can achieve an optimal TCR.

An infrared detector according to the present invention detects an amount of received infrared light using a thermal resistor, wherein the thermal resistor is composed of Pr₁₋ₓCaₓMnO₃ having a perovskite structure, to which a metal oxide having a perovskite structure is added, the metal oxide including at least one of a rare earth metal excepting Pr and an alkaline earth metal excepting Ca.

Also, the metal oxide is any of a manganese oxide, a titanium oxide, an aluminum oxide, a gallium oxide, and a cobalt oxide.

With the above structure, in the thermal resistor, a phase transition temperature and its range width thereof change, compared with that in Pr₁₋ₓCaₓMnO₃. These changes differ depending on the kind of elements to replace with and an amount of replacement thereof.

Therefore, appropriate selections of a hole doping level, a kind of elements to replace with, and an amount of replacement thereof can realize an infrared detector having a higher temperature resolution in a larger temperature range. That is, an operating temperature range of the infrared detector can be extended.

### BRIEF DESCRIPTION OF THE DRAWINGS

FIG. 1 shows a main circuit structure of an infrared imaging device;

FIG. 2 shows a circuit structure of an infrared detector that constitutes the infrared imaging device;

FIG. 3 is a perspective view showing an implementation example of the infrared detector;

FIG. 4 shows a temperature characteristic in an electrical resistivity in La₁₋ₓSrₓTiO₃;

FIG. 5 shows how a phase transition temperature of RNiO₃ differs depending on the kind of R;

FIG. 6 shows a temperature characteristic in an electrical resistivity in La₁₋ₓSrₓMnO₃, which is a representative manganese oxide in which a CMR occurs;

FIG. 7 is a cross-sectional view showing an infrared detector;

FIG. 8 shows an example in which a permanent magnet is attached to an infrared imaging device;

FIG. 9 is a cross-sectional view showing an example in which an electromagnet is attached to an infrared imaging device;

FIG. 10 is a cross-sectional view showing an infrared detector; and

FIG. 11 is a top view showing an infrared detector.

### BEST MODE FOR CARRYING OUT THE INVENTION

The present invention is characterized by using a strongly-correlated electron material as a thermal resistor. Strongly-correlated electron materials are known for undergoing a metal-insulator phase transition at a certain temperature, and having a very high temperature coefficient of resistivity (TCR) in accordance with temperature change at a temperature near the metal-insulator phase transition temperature. Therefore, by using a strongly-correlated electron material as a thermal resistor, an infrared imaging device having a higher temperature resolution can be realized.

The present specification particularly describes the following four metal oxides among strongly-correlated electron materials: (1) a metal oxide in which a part of Pr of Pr₁₋ₓCaₓMnO₃ (PCMO) is replaced with a different rare earth metal, or a part of Ca of Pr₁₋ₓCaₓMnO₃ (PCMO) is replaced with a different alkaline earth metal; (2) La₁₋ₓBₓTiO₃ (where B is an alkaline earth metal); (3) RNiO₃ (where R is an yttrium or a rare earth metal); and (4) La₁₋ₓSrₓMnO₃. Each of the four metal oxides has a perovskite structure and includes a rare earth metal and/or an alkaline earth metal.

### First Embodiment

The following describes a first embodiment using an infrared camera as an example.

An infrared camera according to the first embodiment is an infrared camera having an infrared imaging device according to the present invention, which picks up still images and moving images by causing an infrared light emitted from a subject to enter the infrared imaging device via an optical system such as a lens.

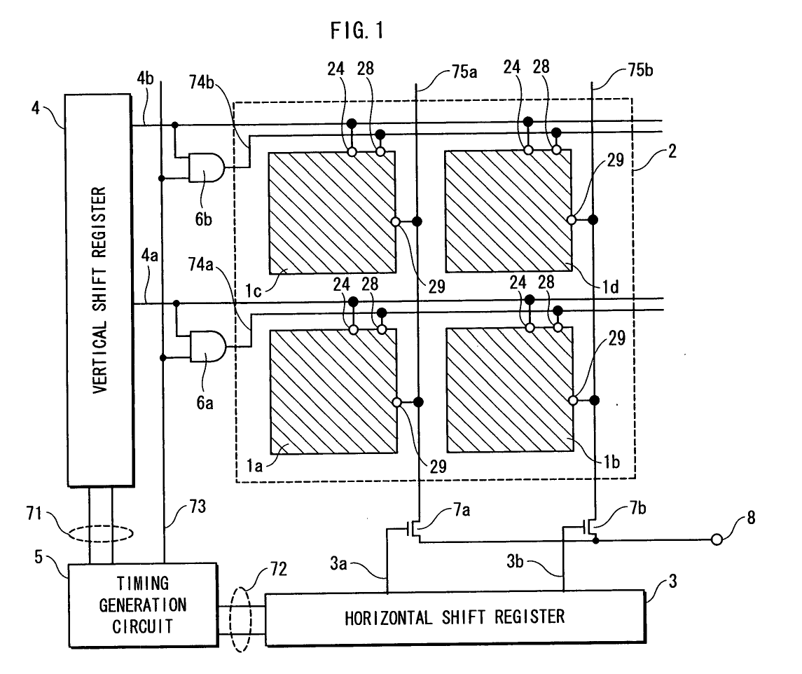

FIG. 1 shows a main circuit structure of the infrared imaging device according to the first embodiment.

The infrared imaging device includes a plurality of infrared detectors 1a, 1b, 1c, and 1d and a detection circuit that detects an amount of change in an electrical resistivity of each of the infrared detectors, the infrared detectors and the detection circuit being formed on a common semiconductor substrate. The detection circuit includes a horizontal shift register 3, a vertical shift register 4, and a timing generation circuit 5, wirings, and the like. For simplicity of the description, the infrared imaging device having two horizontal pixels and two vertical pixels is used here. However, the present invention is not limited to the above-mentioned infrared imaging device.

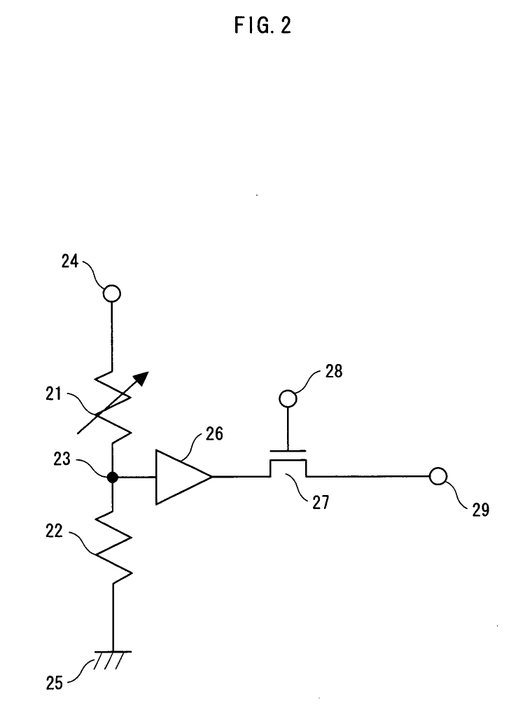

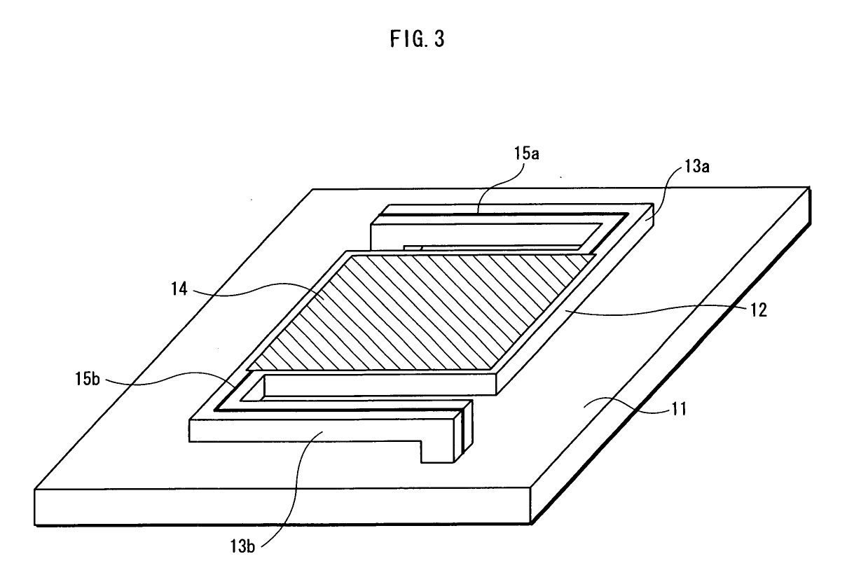

Each of the infrared detectors 1a to 1d has a power terminal 24, a gate terminal 28, and a source terminal 29. Other details are described later (See FIG. 2 and FIG. 3).

The horizontal shift register 3 sequentially switches to either one of signal lines 3a and 3b, whichever has a high level voltage.

The vertical shift register 4 sequentially switches to either one of signal lines 4a and 4b, whichever has a high level voltage.

The timing generation circuit 5 generates a scan start signal and a scan clock signal, and transmits these signals to the vertical shift register 4 and the horizontal shift register 3. Furthermore, the timing generation circuit 5 generates a reading signal, and transmits the reading signal to AND circuits 6a and 6b via a signal line 73.

The AND circuit 6a outputs an AND operation of the signal line 4a and the signal line 73 to the signal line 74a. The AND circuit 6b outputs an AND operation of the signal line 4b and the signal line 73 to the signal line 74b.

The signal line 4a is connected to each power terminal 24 of the infrared detectors 1a and 1b provided in a same row. The signal line 74a is connected to each gate terminal 28 of the infrared detectors 1a and 1b provided in the same row. In the same way, each of the signal lines 4b and 74b is connected to the infrared detectors 1c and 1d provided in a same row.

Also, the signal line 75a is connected to each source terminal 29 of the infrared detectors 1a and 1c provided in a same column. In the same way, the signal line 75b is connected to the infrared detectors 1b and 1d in a same column. Here, each of the signal lines 75a and 75b is connected to the output terminal 8 via transistors 7a and 7b. Continuity of the transistors 7a and 7b is controlled by a voltage in the signal lines 3a and 3b, respectively.

The following describes the operations of the infrared imaging device with the above-described structure.

(1) When the timing generation circuit 5 outputs a scan start signal to the vertical shift register 4, the vertical shift register 4 starts scanning, and the signal line 4a firstly becomes a high level. At this time, the signal line 4b is at a low level.

(2) While the signal line 4a maintains a high level, the signal line 73 becomes a high level by a reading signal generated by the timing generation circuit 5. At this time, the signal line 74a becomes a high level by the AND circuit 6a. Also, the signal line 74b becomes a low level by the AND circuit 6b.

(3) When the signal lines 4a and 74a become a high level, each power terminal 24 and gate terminal 28 of the infrared detectors 1a and 1b become a high level, and each voltage signal of the infrared detectors 1a and 1b is outputted via the source terminal 29.

(4) While the signal lines 4a and 74a maintains a high level, the timing generation circuit 5 outputs a scan start signal to the horizontal shift register 3, the horizontal shift register 3 starts scanning, and the signal line firstly 3a becomes a high level. At this time, the signal line 3b is at a low level. This causes the transistor 7a to be conductive and as a result, a voltage signal of the infrared detector 1a is transmitted to the output terminal 8. Then, the signal line 3a becomes a low level. And simultaneously, the signal line 3b becomes a high level. This causes the transistor 7b to be conductive, and as a result a voltage signal of the infrared detector 1b is transmitted to the output terminal 8.

(5) Next, the vertical shift register 4 switches the signal line 4b to a high level, and simultaneously switches the signal line 4a to a low level. Subsequently, the above-described operations (1) to (4) are repeated to sequentially transmit each voltage signal of the infrared detectors to the output terminal 8.

An output signal outputted from the output terminal 8 is sequentially stored in a memory of the infrared camera. When output signals corresponding to one screen have been stored in the memory, image processing is performed to generate image data.

FIG. 2 shows a circuit structure of an infrared detector that constitutes the infrared imaging device according to the present embodiment.

Terminals (24, 28, and 29) shown in FIG. 2 correspond to the terminals (24, 28, and 29) shown in FIG. 1, respectively.

A thermal resistor 21 and a reference resistance 22 are serially connected between the power terminal 24 and a ground 25. An electrical resistivity of the thermal resistor 21 changes in accordance with a temperature change thereof. Accordingly, a voltage of a voltage dividing point 23 changes depending on the electrical resistivity change. The voltage change in the voltage dividing point 23 is a voltage signal that corresponds to an amount of received infrared light in the infrared detector. The voltage signal is amplified by an amplifier 26, and outputted to the source terminal 29 via a transistor 27. The transistor 27 functions as a switch for conducting an electric current between a drain-source when the gate terminal 28 is at a high level, and for not conducting an electric current between the drain-source when the gate terminal 28 is at a low level.

FIG. 3 is a perspective view showing an implementation example of the infrared detector according to the present embodiment.

A membrane 12 is supported by supporting legs 13a and 13b provided on a substrate 11. A thermal resistor 14 is a thin film formed on the membrane 12, and is connected to an external circuit via metal wirings 15a and 15b. Note that each of the supporting legs 13a and 13b preferably has a higher thermal resistance in order to thermally isolate the thermal resistor 14 from the substrate 11.

In the present embodiment, a metal oxide is used as the thermal resistor 14, the metal oxide being in which a part of Pr of Pr₁₋ₓCaₓMnO₃ (PCMO) is replaced with a different rare earth metal, or a part of Ca of Pr₁₋ₓCaₓMnO₃ (PCMO) is replaced with a different alkaline earth metal.

As one of strongly-correlated electron materials, manganese oxides having a perovskite structure expressed by a chemical formula of A₁₋ₓBₓMnO₃ (where A is a rare earth metal, and B is an alkaline earth metal) are particularly known for undergoing a metal-insulator phase transition from a low temperature metal phase to a high temperature insulator phase, at a temperature near a ferromagnetic transition temperature. This metal-insulator phase transition is caused by an Mn 3d electron, and so a phase transition temperature thereof is determined depending on an amount of supply of electrons to a 3d orbital, a band structure of the 3d orbital, and the like.

Therefore, in the case of Pr₁₋ₓCaₓMnO₃, replacement of a part of a trivalent rare earth metal Pr in PrMnO₃ with a divalent alkaline earth metal Ca can decrease an amount of supply of electrons to a 3d orbital (equivalent to hole doping) to change a phase transition temperature thereof.

Furthermore, in Pr₁₋ₓCaₓMnO₃, replacement of a part of Pr with a different rare earth metal, or replacement of a part of Ca with a different alkaline earth metal can change a band structure of a 3d orbital to change a phase transition temperature thereof. When a part of Pr is replaced with a different rare earth metal, a crystal lattice having a perovskite structure distorts because of difference in ionic radius between Pr and the rare earth metal to change a band structure of a 3d orbit.

Note that this replacement is realized by forming as a film a composite material in which LaTiO₃, for example, is added to Pr₁₋ₓCaₓMnO₃ using a laser evaporation method, a CVD method, a sol gel method, and the like. In this case, Pr_{1-x-y}La_{y}CaₓMnO₃ is formed as a film, in which a part of Pr is replaced with La.

Note that, without limitation to LaTiO₃, any metal oxide having a perovskite structure expressed by RMO₃ (where R is a rare earth metal or an alkaline earth metal, and M is a transition metal) can be employed for replacement in the same way as LaTiO₃.

Furthermore, replacement of a part of Ca with Sr or Ba, for example, can obtain the same effect. A transition metal M in RMO₃ includes Mn, Ti, Al, Ga, and Co.

In this way, by using a strongly-correlated electron material having a higher TCR as a thermal resistor, an infrared imaging device having a higher temperature resolution can be realized. Also, among strongly-correlated electron materials, particularly in Pr₁₋ₓCaₓMnO₃, by replacing a part of Pr with a different rare earth metal or replacing a part of Ca with a different alkaline earth metal, the following effects can be obtained.

(1) A change in a hole doping level x of Pr₁₋ₓCaₓMnO₃ can change a phase transition temperature and its range thereof.

(2) In Pr₁₋ₓCaₓMnO₃, replacement of a part of Pr with a different rare earth metal or replacement of a part of Ca with a different alkaline earth metal can change a phase transition temperature and its range thereof. Note that this change differs depending on the kind of elements to replace with and an amount of replacement thereof.

Therefore, appropriate selections of a hole doping level, a kind of elements to replace with, and an amount of replacement thereof can realize an infrared detector having a higher temperature resolution in a larger temperature range. And so an operating temperature range of the infrared detector can be extended.

### Second Embodiment

An infrared camera according to a second embodiment has a structure nearly same as that in the infrared camera according to the first embodiment. The second embodiment differs from the first embodiment in selection of a material as a thermal resistor.

In the second embodiment, La₁₋ₓBₓTiO₃ (where B is an alkaline earth metal) is used as the thermal resistor 14.

LaTiO₃ having a perovskite structure is a typical Mott insulator in which one electron occupies a 3d orbital. A Mott transition of LaTiO₃ is caused by a Ti 3d electron, and so a Mott transition temperature thereof is determined depending on an amount of supply of electrons to the 3d orbital, a band structure of the 3d orbital, and the like.

Therefore, like in the case of La₁₋ₓBₓTiO₃, by replacing a part of a trivalent rare earth metal La with a divalent alkaline earth metal B in LaTiO₃, an amount of supply of electrons to a 3d orbital is decreased (equivalent to hole doping) to change a phase transition temperature thereof.

Note that this replacement can be realized by mixing La and an alkaline earth metal B in a raw material stage at a predetermined molar ratio, and melting the mixture to grow a crystal.

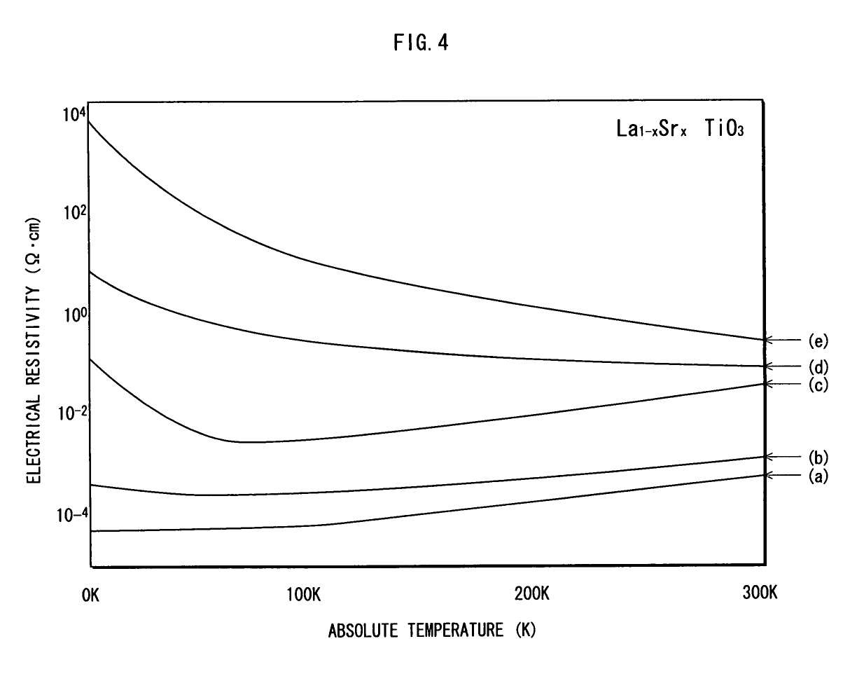

FIG. 4 shows a temperature characteristic in an electrical resistivity of La₁₋ₓSrₓTiO₃.

Note that each of reference alphabets (a) to (e) indicates a temperature characteristic in an electrical resistivity in different hole doping levels. A descending order of temperature characteristic depending on hole doping level is as follows: (a)>(b)>(c)>(d)>(e). FIG. 4. shows that a temperature characteristic in an electrical resistivity greatly differs depending on hole doping levels. FIG. 4. further shows that a TCR is higher in a large temperature range of 0 K to 300 K depending on hole doping levels. (Reference: “Strongly-correlated Electron and Oxide”, Yoshinori Tokura, ISBN: 4-00-011132-9)

Note that use of a different alkaline earth metal instead of Sr for the replacement can obtain the same effect. In this case, since an ionic radius of an alkaline earth metal B differs from an ionic radius of the different alkaline earth metal because of difference in an element of alkaline earth metal B, it is expected that a temperature characteristic in an electrical resistivity thereof differs from that shown in FIG. 4. Therefore, by using La₁₋ₓBₓTiO₃ (where B is an alkaline earth metal) as the thermal resistor 14, the following effects can be obtained.

(1) A change in a hole doping level x of La₁₋ₓBₓTiO₃ can change a temperature characteristic in an electrical resistivity thereof.

(2) In La₁₋ₓBₓTiO₃, a change in the kind of alkaline earth metals B can change a temperature characteristic in an electrical resistivity thereof.

Therefore, appropriate selections of a hole doping level, a kind of elements to replace with, and an amount of replacement thereof enable manufacture of a thermal resistor having an optimal specification in an operating temperature range in accordance with purposes.

### Third Embodiment

An infrared camera according to a third embodiment has a structure nearly same as that in the infrared camera according to the first embodiment. The third embodiment differs from the first embodiment in selection of a material as a thermal resistor.

In the third embodiment, RNiO₃ (where R is an yttrium or a rare earth metal) is used as the thermal resistor 14.

It is known that metal-insulator phase transitions occur not only in manganese oxides having a perovskite structure but also in other compounds. One representative of such compounds is a nickel oxide expressed by RNiO₃ having a perovskite structure.

RNiO₃ is a typical Mott insulator whose metal-insulator phase transition temperature differs depending on the kind of R.

It is considered that the phase transition temperature of RNiO₃ differs depending on the kind of R because a transfer energy of a 3d electron between R and an adjoining nickel differs depending on an ionic radius of R. The phase transition temperature depends on a balance of a Coulomb repulsion energy between electrons and a transfer energy between the electrons. That is, the phase transition temperature differs depending on an ionic radius of R.

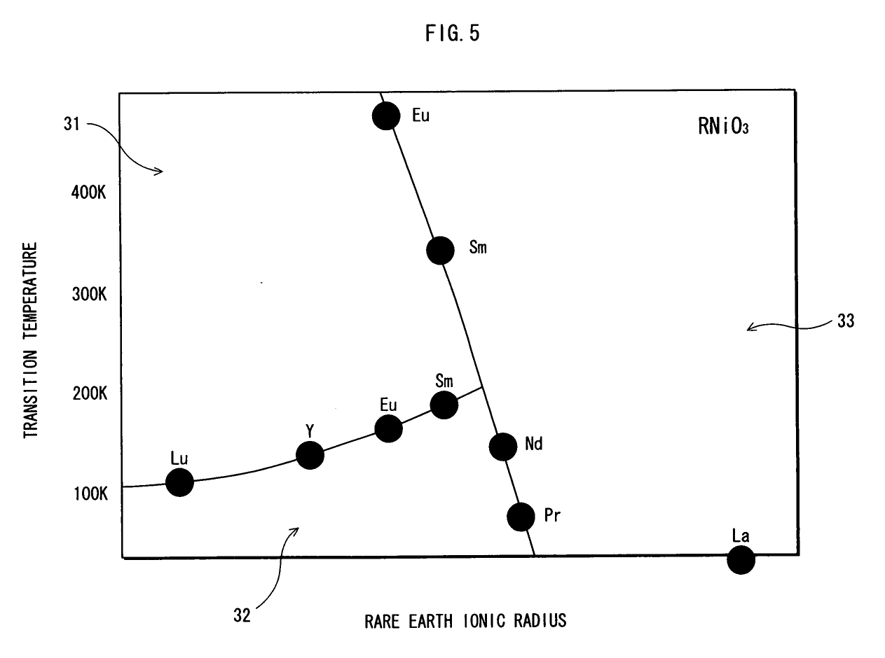

FIG. 5 shows how a phase transition temperature of RNiO₃ differs depending on the kind of R.

Reference numerical 31 indicates a paramagnetic insulator, reference numerical 32 indicates an antiferromagnetic insulator, and reference numerical 33 indicates a metal phase. As shown in FIG. 5, each of insulator-metal phase transition temperatures of PrNiO₃, NdNiO₃, and SmNiO₃, is at approximately 100 K, approximately 150 K, and approximately 300 K, respectively. (Reference: “Strongly-correlated Electron and Oxide”, Yoshinori Tokura, ISBN: 4-00-011132-9)

As described above, an insulator-metal phase transition temperature changes over a large range of no more than 100 K to no less than 400 K depending on an ionic radius of R.

Therefore, by using RNiO₃ (where R is an yttrium or a rare earth metal) as the thermal resistor 14, the following effect can be obtained.

(1) In RNiO₃, a change in the kind of rare earth metals R can change an insulator-metal phase transition temperature thereof.

Therefore, an appropriate selection of a kind of metals R enables manufacture of a thermal resistor having an optimal specification in an operating temperature range in accordance with purposes.

Note that, in the same way as that in the first and second embodiments, in RNiO₃, replacement of a part of R with an element other than R among an yttrium, a rare earth metal, and an alkaline earth metal can change an insulator-metal phase transition temperature and its range thereof.

Therefore, appropriate selections of a hole doping level, a kind of elements to replace with, and an amount of replacement thereof enable manufacture of a thermal resistor having an optimal specification in an operating temperature range in accordance with purposes.

### Fourth Embodiment

An infrared camera according to a fourth embodiment has a structure nearly same as that in the infrared camera according to the first embodiment. The fourth embodiment differs from the first embodiment in selection of a material as a thermal resistor. Also, the infrared camera according to the fourth embodiment has a unit for applying a magnetic field.

In the fourth embodiment, La₁₋ₓSrₓMnO₃ is used as the thermal resistor 14.

In recent years, a phenomenon called a Colossal Magnetic Resistance (CMR) has occurred in manganese oxides having a perovskite structure. The CMR is a phenomenon in which magnetic properties of manganese oxide change depending on an intensity of an external magnetic field, and accordingly an electrical resistivity greatly changes.

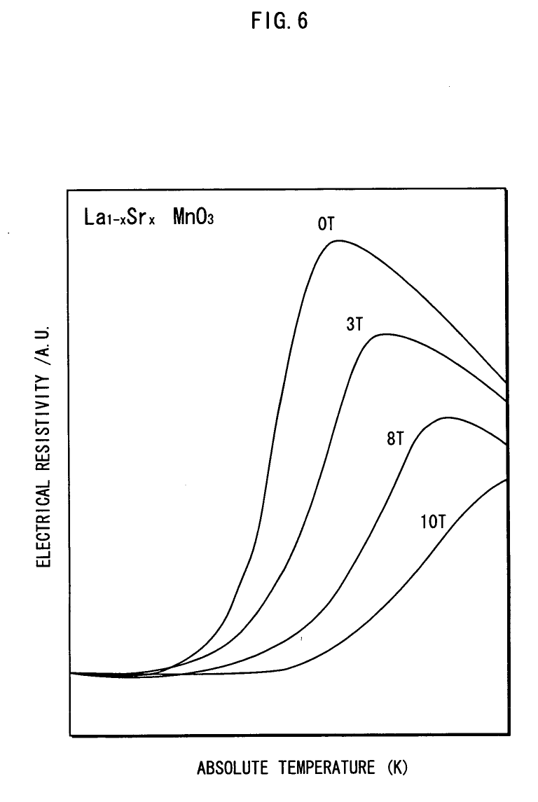

FIG. 6 shows a temperature characteristic in the electrical resistivity of La₁₋ₓSrₓMnO₃, which is a representative manganese oxide in which a CMR occurs.

La₁₋ₓSrₓMnO₃ has an electrical resistivity that increases in accordance with in a temperature decrease, and transits to a ferromagnetic material near 300 K. With this transition, the electrical resistivity rapidly decreases, and then La₁₋ₓSrₓMnO₃ shows a metal behavior at a lower temperature. Also, in a magnetic field, with an increase in intensity of the magnetic field, a ferromagnetic transition temperature (Curie temperature) shifts to a higher temperature, and then La₁₋ₓSrₓMnO₃ transits from a higher temperature to a metal state. (Reference: “Strongly-correlated Electron and Oxide”, Yoshinori Tokura, ISBN: 4-00-011132-9)

In La₁₋ₓSrₓMnO₃, a metal-insulator phase transition occurs in a very narrow temperature range in general, thereby a greatly higher TCR can be obtained.

However, when this La₁₋ₓSrₓMnO₃ is used as a thermal resistor, a temperature compensation device (e.g. a peltier device or a stirling cooling apparatus) is needed for adjusting a temperature of an infrared detector to be in the phase transition temperature range. Here, by providing La₁₋ₓSrₓMnO₃ in a magnetic field, though a TCR is lowered compared with the case where the magnetic field is not applied, an electrical resistivity can be changed over a greatly larger temperature range. As a result, an infrared imaging device having a single thermal resistor usable over a larger temperature range can be realized.

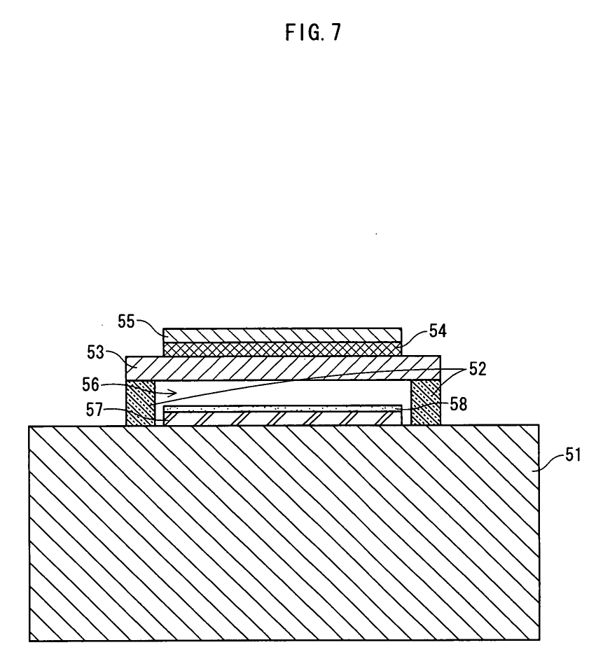

FIG. 7 is a cross-sectional view showing an infrared detector.

A membrane 53 is supported by supporting legs 52 provided on a substrate 51 with a space 56 therebetween. A thermal resistor 54 is a thin film formed on the membrane 53, and an infrared absorbing film 55 is further formed thereon. Immediately below the thermal resistor 54, a magnetic thin film 57 and an infrared reflecting film 58 are formed on the substrate 51. An infrared light enters the infrared absorbing film 55 from above to be absorbed. In the thermal resistor 54, an electrical resistivity changes in accordance with a change in a temperature of the infrared absorbing film 55, and an amount of the change in the electrical resistivity is read by an external reading circuit. Furthermore, an infrared light that has not been absorbed by the infrared absorbing film 55 is reflected by the infrared reflecting film 58, and reenters the infrared absorbing film 55. The magnetic thin film 57 is a magnetic material for applying a magnetic field to the thermal resistor 54. Note that the supporting legs 52 each preferably has a higher thermal resistance in order to thermally isolate the membrane 53 from the substrate 51.

With the above structure, the magnetic thin film 57 is provided in a lower part of each infrared detector, thereby suppressing an influence of the magnetic field on external circuits and the like. Moreover, the magnetic thin film 57 and the thermal resistor 54 are adjacent to each other, thereby efficiently applying a uniform magnetic field to the thermal resistor 54.

Therefore, by using La₁₋ₓSrₓMnO₃ as the thermal resistor 54 in the above structure, the following effect can be obtained.

(1) A change in an intensity of a magnetic field generated by the magnetic thin film 57 can change the temperature characteristic in the electrical resistivity of La₁₋ₓSrₓMnO₃.

Therefore, an appropriate selection of an intensity of a magnetic field enables manufacture of a thermal resistor having an optimal specification in an operating temperature range in accordance with purposes.

Moreover, a higher intensity of a magnetic field enables manufacture of a thermal resistor having a higher TCR in a larger temperature range.

Although the case of La₁₋ₓSrₓMnO₃ is described in the fourth embodiment, it is considered that a use of other manganese oxides having a perovskite structure can achieve the same effect. Accordingly, Pr₁₋ₓCaₓMnO₃ may be employed, for example.

Note that the unit for applying a magnetic field to a thermal resistor is not limited to the above example. The following may be employed.

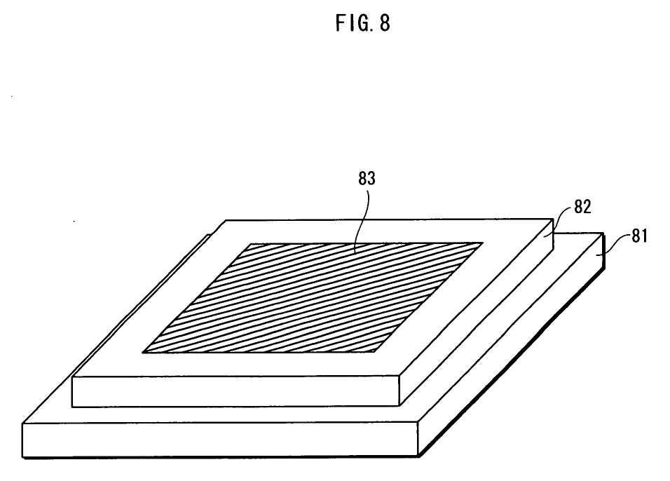

FIG. 8 shows an example in which a permanent magnet is attached to an infrared imaging device.

As shown in FIG. 8, an infrared imaging device 82 is mounted on an upper part of a permanent magnet 81. Reference numerical 83 indicates an imaging pickup unit of the infrared imaging device 82, and an infrared light enters a surface of this image pickup unit. With this structure, an infrared imaging device mounted on a permanent magnet can be manufactured without any accessories. Also, magnets have no need to be miniaturized, thereby an infrared imaging device can be easily manufactured at lower costs.

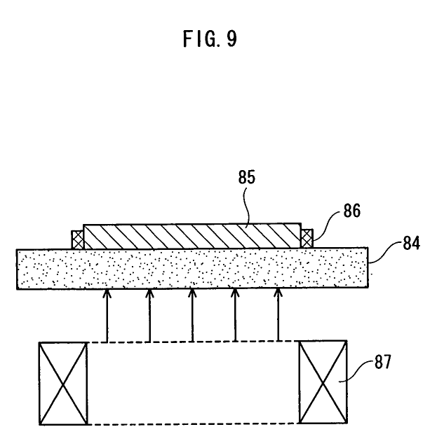

FIG. 9 is a cross-sectional view showing an example in which an electromagnet is attached to an infrared imaging device.

As shown in FIG. 9, an infrared imaging device 85 is mounted on a circuit substrate 84, and is electrically connected with the circuit substrate 84 via an electrode 86. An electromagnet 87 is mounted on a lower part of the circuit substrate 84.

The electromagnet 87 can change an intensity of a magnetic field to be generated depending on an amount of an electric current to be applied to a coil. In the structures shown in FIG. 7 and FIG. 8, since the permanent magnet is used, users have a difficulty in changing an intensity of a magnetic field after shipment of infrared cameras. However, in the structure shown in FIG. 9, users can change an intensity of a magnetic field after shipment of infrared cameras. Therefore, an optimal intensity of a magnetic field can be adjusted in accordance with a temperature environment where an infrared camera is installed.

### Fifth Embodiment

In the first to fourth embodiments, the change of the band structure of the 3d orbital in the metal oxide having a perovskite structure changes the phase transition temperature thereof. The band structure of the 3d orbital can be changed depending on distortion in a crystal lattice having a perovskite structure.

In a fifth embodiment, by using a metal oxide having a perovskite structure as a thermal resistor, and applying a stress to the thermal resistor, a band structure of a 3d orbital is changed and a phase transition temperature thereof is changed.

Specifically, a thermal resistor is formed on an insulator whose lattice constant differs from a lattice constant of the thermal resistor. With this structure, an atom moves so as to achieve a lattice constant match between the thermal resistor and the insulator on a contact surface of the thermal resistor and an insulator, and then an internal stress is generated between the thermal resistor and the insulator. The internal stress generated by the difference in lattice constant changes a metal-insulator phase transition temperature of the thermal resistor.

In this way, by using a metal oxide having a perovskite structure as the thermal resistor, and forming the thermal resistor on an insulator whose lattice constant differs from a lattice constant in the thermal resistor, the following effect can be obtained.

(1) A change in a combination of a thermal resistor and an insulator can change a temperature characteristic in an electrical resistivity of the thermal resistor.

Therefore, appropriate selections of a combination of a thermal resistor and an insulator enable manufacture of a thermal resistor having an optimal specification in an operating temperature range in accordance with purposes.

Without limitation to an internal stress, an application of an external stress can achieve an effect same as that in the internal stress.

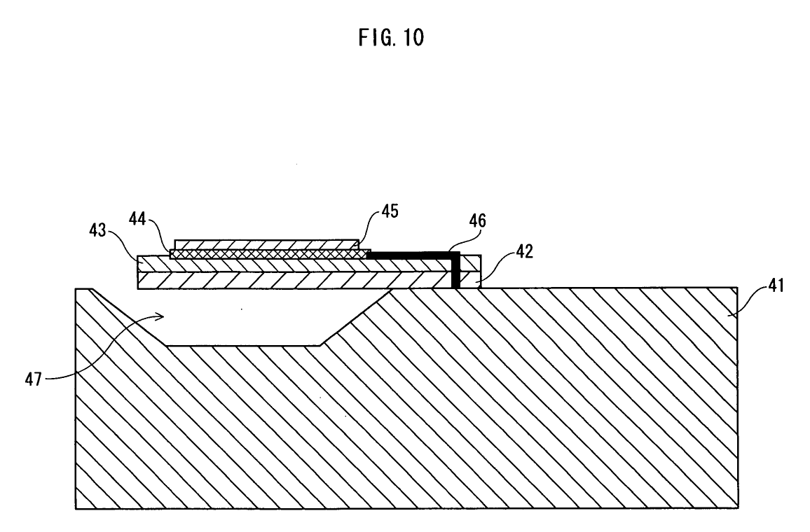

FIG. 10 is a cross-sectional view showing an infrared detector.

A part of a piezoelectric element 42 contacts with a substrate 41, and most parts thereof are isolated from the substrate 41 with a space 47 therebetween, in order to increase a thermal resistance therebetween and keep a degree of freedom in deformation of the piezoelectric element 42. A thermal resistor 44 is a thin film formed on an insulator 43, and an infrared absorbing film 45 is further formed thereon. An infrared light enters the infrared absorbing film 45 from above to be absorbed. In the thermal resistor 44, an electrical resistivity changes in accordance with a change in a temperature of the infrared absorbing film 45, and an amount of the change in the electrical resistivity is read by an external reading circuit via a reading electrode 46. Note that the thermal resistor 44 preferably has a surface contact with the insulator 43 for uniform application of an external stress to the thermal resistor 44. Moreover, the thermal resistor 44 needs no direct contact with the piezoelectric element 42, and a different kind material may be therebetween.

In the above structure, the piezoelectric element 42 applies an external stress to the thermal resistor 44 in accordance with a given voltage. This changes a temperature characteristic in an electrical resistivity of the thermal resistor 44.

In the piezoelectric element 42, an intensity of a stress can be changed depending on a level of a given voltage. With the structure shown in FIG. 10, by changing a voltage, users can change an intensity of a stress after shipment of infrared cameras. Therefore, an optimal intensity of a stress can be adjusted in accordance with a temperature environment where an infrared camera is installed.

### Sixth Embodiment

In the first to fifth embodiments, the change of the band structure of the 3d electron in the metal oxide having a perovskite structure changes magnetic properties thereof and the temperature characteristic in the electrical resistivity.

In a sixth embodiment, a metal oxide having a perovskite structure is used as a thermal resistor, and by applying an electric field to the thermal resistor, a band structure of a 3d orbital is changed and so a temperature characteristic in an electrical resistivity is changed.

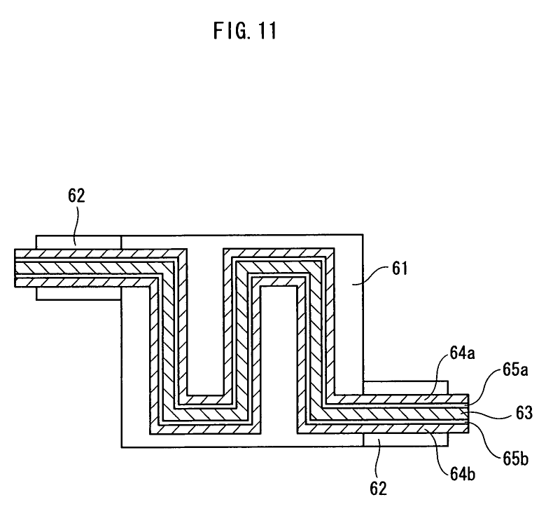

FIG. 11 is a top view showing an infrared detector.

A membrane 61 is supported by supporting legs 62 provided on a substrate. A thermal resistor 63 is a thin film formed on the membrane 61. An infrared light enters from above. In the thermal resistor 63, an electrical resistivity changes in accordance with a temperature change caused by the entered infrared light, and an amount of the change in the electrical resistivity is read by an external reading circuit.

Electrodes 64a and 64b are arranged along the thermal resistor 63 so as to sandwich the thermal resistor 63. When a voltage is applied to the electrodes 64a and 64b, an electric field is generated therebetween to be applied to the thermal resistor 63. Since the electrodes 64a and 64b are arranged along the thermal resistor 63, a uniform electric field can be applied to the thermal resistor 63. Moreover, the electrodes 64a and 64b do not act as an obstacle when an infrared light enters from above. Note that the electrodes 64a and 64b and the thermal resistor 63 each is insulated by insulators 65a and 65b. Also, the thermal resistor 63 is electrically connected with the reading circuit that reads the electrical resistivity thereof via a reading electrode. An external electric field is preferably applied perpendicular to the direction in which the electric field is applied by the reading electrode. The supporting legs 62 each preferably has a higher thermal resistance in order to thermally isolate the membrane 61 from the substrate.

In the above structure, application of a voltage to the electrodes 64a and 64b generates an electric field. A degenerated energy level of a 3d orbital is known for being split in an electric field due to a Stark effect. This changes a band structure of a 3d orbital in a metal oxide having a perovskite structure, and thereby changing a temperature characteristic in an electrical resistivity thereof.

In this way, by using a metal oxide having a perovskite structure as the thermal resistor 63, and applying an electric field to the thermal resistor 63, the following effect can be obtained.

(1) A change in an intensity of an electric field can change a temperature characteristic in an electrical resistivity of a thermal resistor.

Therefore, an appropriate selection of an intensity of an electric field enables manufacture of a thermal resistor having an optimal specification in an operating temperature range in accordance with purposes. Furthermore, in the electrodes 64a and 64b, an intensity of an electric field can be changed depending on a level of a given voltage. With the structure shown in FIG. 11, users can change an intensity of a magnetic field after shipment of infrared cameras. Therefore, an optimal intensity of an electric field can be adjusted in accordance with a temperature environment where an infrared camera is installed.

### INDUSTRIAL APPLICABILITY

The present invention can be applied to infrared cameras that can recognize an object as an image in a dark field, such as small surveillance cameras for security and night vision cameras mounted on cars.

1-5. (canceled)

6. An infrared detector that detects an amount of received infrared light using a thermal resistor, wherein
the thermal resistor is composed of LaTiO₃ having a perovskite structure in which a part of La is replaced with an alkaline earth metal.

7-8. (canceled)

9. An infrared detector that detects an amount of received infrared light using a thermal resistor, wherein
the thermal resistor is composed of RNiO₃ having a perovskite structure in which a part of R is replaced with an alkaline earth metal, where R is an yttrium or a rare earth metal.

10-13. (canceled)

14. An infrared detector comprising:
a thermal resistor composed of a metal oxide having a perovskite structure;
a stress applying unit operable to apply a stress to the thermal resistor;
a detecting unit operable to, in a state where the stress is being applied to the thermal resistor by the stress applying unit, detect an amount of received infrared light using the thermal resistor; and
a changing unit operable to cause the stress applying unit to change an intensity of the stress.

15. An infrared detector comprising:
a thermal resistor composed of a metal oxide having a perovskite structure;
an electric field applying unit operable to apply an electric field to the thermal resistor, the electric field applying unit and the thermal resistor sandwiching an insulator; and
a detecting unit operable to, in a state where the electric field is being applied to the thermal resistor by the electric field applying unit, detect an amount of received infrared light using the thermal resistor.

16. The infrared detector of claim 15 further comprising
a changing unit operable to cause the electric field applying unit to change an intensity of the electric field.

17. An infrared detector that detects an amount of received infrared light using a thermal resistor, wherein
the thermal resistor is composed of Pr₁₋ₓCaₓMnO₃ having a perovskite structure, to which a metal oxide having a perovskite structure is added, the metal oxide including at least one of a rare earth metal excepting Pr and an alkaline earth metal excepting Ca.

18. The infrared detector of claim 17, wherein oxide, a titanium oxide, an aluminum oxide, a gallium oxide, and a cobalt oxide.
